(19) United States
(12) Patent Application Publication
(10) Pub. No.: US 2025/0126868 A1
(43) Pub. Date: Apr. 17, 2025

(54) METHODS OF FORMING SEMICONDUCTOR STRUCTURES

(71) Applicant: NANYA TECHNOLOGY CORPORATION, New Taipei city (TW)

(72) Inventor: Ying-Cheng CHUANG, Taoyuan City (TW)

(21) Appl. No.: 18/488,696

(22) Filed: Oct. 17, 2023

(51) Int. Cl. H01L 29/40; H01L 29/423

(52) U.S. Cl. CPC H10D 64/01; H10D 64/513

(57) ABSTRACT

A method of forming a semiconductor structure includes the following operations. A trench is formed in a substrate. A dielectric layer is formed to cover an inner surface of the trench. A bottom conductive layer is deposited on the dielectric layer and in the trench at a first temperature of 350° C. to 450° C. An annealing process is performed on the bottom conductive layer at a second temperature greater than or equal to 470° C. A portion of the bottom conductive layer is removed to form a recess on the bottom conductive layer and in the trench. A top conductive layer is formed in the recess.

### BACKGROUND

### Field of Invention

The present disclosure relates to methods of forming semiconductor structures.

### Description of Related Art

Semiconductor devices have applications in many electronic devices, including communication devices, automotive electronics, and other technology platforms. With increased demand for improved functionality and miniaturization in portable devices such as cell phones, digital cameras, and laptop computers, there is a need to provide package-on-package semiconductor devices with flexible interconnect geometry compatible with pick-and-place and molding processes while also having minimal package size. Package-on-package stacking technology is becoming widely used in semiconductor device manufacturing and will play an increasingly important role in the future. Package-on-package stacking technology can result in better electrical performance of the device, since the shorter routing of interconnections between circuits results in faster signal propagation and reduction in noise and cross-talk. However, a variety of issues arise during the package-on-package stacking process and impact the final electrical characteristics, quality, and yield. Therefore, challenges remain in achieving improved performance, quality, yield, and reliability.

### SUMMARY

The present disclosure provides a method of forming a semiconductor structure. The method includes the following operations. A trench is formed in a substrate. A dielectric layer is formed to cover an inner surface of the trench. A bottom conductive layer is deposited on the dielectric layer and in the trench at a first temperature of 350° C. to 450° C. An annealing process is performed on the bottom conductive layer at a second temperature greater than or equal to 470° C. A portion of the bottom conductive layer is removed to form a recess on the bottom conductive layer and in the trench. A top conductive layer is formed in the recess.

In some embodiments, the bottom conductive layer includes titanium nitride (TiN).

In some embodiments, the top conductive layer includes polysilicon.

In some embodiments, the second temperature is 470° C. to 650° C.

In some embodiments, the annealing process is performed by rapid thermal annealing (RTA).

In some embodiments, during performing the annealing process, an annealing time is between 5 minutes to 100 minutes.

In some embodiments, the annealing process is performed under an inert gas atmosphere or a nitrogen gas atmosphere.

In some embodiments, the trench has a width of 12 nm to 30 nm.

In some embodiments, depositing the bottom conductive layer is performed by chemical vapor deposition (CVD) or physical vapor deposition (PVD).

In some embodiments, the method further includes before forming the trench in the substrate, forming a doped region in the substrate, in which after forming the trench in the substrate, the trench penetrates through the doped region.

The present disclosure provides a method of forming a semiconductor structure. The method includes the following operations. A first trench and a second trench are formed in a substrate. A dielectric layer is formed to cover a first inner surface of the first trench and a second inner surface of the second trench. A titanium nitride layer is deposited on the dielectric layer and in the first trench and the second trench at a first temperature of 350° C. to 450° C. An annealing process is performed on the titanium nitride layer at a second temperature greater than or equal to 470° C.

In some embodiments, the first trench has a first top edge, the second trench has a second top edge adjacent to the first top edge, and a distance between the first top edge and the second top edge is 12 nm to 30 nm.

In some embodiments, the second temperature is 470° C. to 650° C.

In some embodiments, during performing the annealing process, an annealing time is between 5 minutes to 100 minutes.

In some embodiments, the annealing process is performed by rapid thermal annealing.

In some embodiments, the method further includes the following operations. After performing the annealing process on the titanium nitride layer, a portion of the titanium nitride layer is removed to expose a sidewall and a top surface of the dielectric layer. A polysilicon layer is formed on the titanium nitride layer and in the first trench and the second trench. A portion of the polysilicon layer is removed to expose the sidewall and the top surface of the dielectric layer.

In some embodiments, the method further includes after removing the portion of the polysilicon layer, forming an insulating capping layer to fill the first trench and the second trench.

In some embodiments, the method further includes before forming the first trench and the second trench in the substrate, forming a doped region in the substrate, in which after forming the first trench and the second trench in the substrate, the first trench and the second trench penetrate through the doped region.

In some embodiments, a first depth of the first trench is greater than a second depth of the second trench.

In some embodiments, the method further includes before forming the first trench and the second trench in the substrate, forming an isolation structure in the substrate, in which after forming the first trench and the second trench in the substrate, the first trench penetrates into the isolation structure.

It is to be understood that the foregoing general description and the following detailed description are merely exemplary and explanatory, and are intended to provide further illustration of the present disclosure.

### BRIEF DESCRIPTION OF THE DRAWINGS

The present disclosure can be more fully understood by reading the following detailed description of the embodiment, with reference made to the accompanying drawings as follows.

FIGS. 1-9 are schematic cross-sectional views of the intermediate stages of forming a semiconductor structure according to various embodiments of the present disclosure.

FIG. 10 is a top view of a semiconductor structure in accordance with some embodiments of the present disclosure.

FIG. 11 shows the resistivity of titanium nitride layers in Examples 1-6 and Comparative Example 1 of the present disclosure.

FIG. 12 shows the resistivity of titanium nitride layers of Examples 6-8 and Comparative Example 1 in the present disclosure.

FIG. 13 shows the space imbalance of titanium nitride layers of Examples 6-8 and Comparative Examples 1-2 in the present disclosure.

### DETAILED DESCRIPTION

Reference will now be made in detail to the embodiments of the present disclosure, examples of which are illustrated in the accompanying drawings. Wherever possible, the same reference numbers are used in the drawings and the description to refer to the same or like parts.

The following embodiments are disclosed with accompanying diagrams for detailed description. For illustration clarity, many details of practice are explained in the following descriptions. However, it should be understood that these details of practice do not intend to limit the present disclosure. That is, these details of practice are not necessary in parts of embodiments of the present disclosure. Furthermore, for simplifying the drawings, some of the conventional structures and elements are shown with schematic illustrations.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present disclosure.

With the rapid growth of the electronic industry, the development of semiconductor devices has achieved high performance and miniaturization. As the size of semiconductor devices, such as dynamic random access memory (DRAM) devices, shrinks, the gate channel length decreases correspondingly. Consequently, a short-channel effect may occur. To deal with such a problem, a buried-channel array transistor (BCAT) device has been proposed. The present disclosure provides a method of forming a semiconductor structure. The semiconductor structure includes a bottom conductive layer and a top conductive layer that can be used as a word-line structure of a BCAT. During the manufacturing process, the bottom conductive layer is deposited in trenches under a low temperature of 350° C. to 450° C. and then treated with an annealing process with a temperature higher than the deposition temperature to lower its resistivity. Even if the protruding portions between the trenches have small widths and/or the trenches are narrow, word-line wiggling or word-line collapse can be prevented due to low deposition temperature.

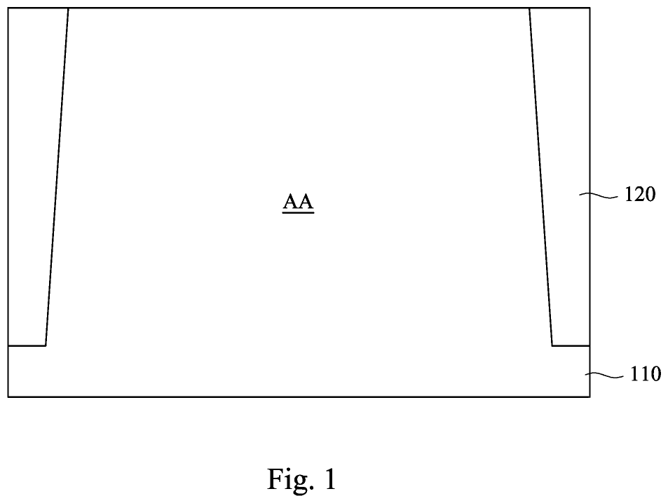

The present disclosure provides a method of forming a semiconductor structure. FIGS. 1-9 are schematic cross-sectional views of the intermediate stages of forming a semiconductor structure according to various embodiments of the present disclosure. Although below using a series of operations or steps described in this method disclosed, the order of these operations or steps shown should not be construed to limit the present disclosure. For example, certain operations or steps may be performed in different orders and/or concurrently with other steps. Moreover, not all steps must be performed to achieve the depicted embodiment of the present disclosure. Furthermore, each operation or procedure described herein may contain several sub-steps or actions.

Reference is made to FIG. 1. A substrate 110 is received. In some embodiments, an isolation structure 120 is formed in the substrate 110 and surrounds at least one active area AA of the substrate 110. One active area AA is one protruding portion of the substrate 110. The number of the active area AA is not limited to 1. The number of the active area AA can be adjusted according to the design requirements. In some other embodiments, a plurality of active area AA protrudes from the substrate 110, and each active area AA is surrounded by the isolation structure 120. In some embodiments, the substrate 110 is a silicon substrate. Alternatively, the substrate 110 may include another elementary semiconductor, such as germanium; a compound semiconductor including silicon carbide, gallium arsenide, gallium phosphide, indium phosphide, indium arsenide, and/or indium antimonide; an alloy semiconductor including SiGe, GaAsP, AlinAs, AlGaAs, GaInAs, GaInP, and/or GaInAsP; or combinations thereof. In some embodiments, the isolation structure 120 includes silicon oxide, silicon nitride, silicon oxynitride, or other suitable materials. In some embodiments, the isolation structure 120 is a shallow trench isolation (STI) structure. The isolation structure 120 may be formed by physical vapor deposition (PVD), chemical vapor deposition (CVD), or the like.

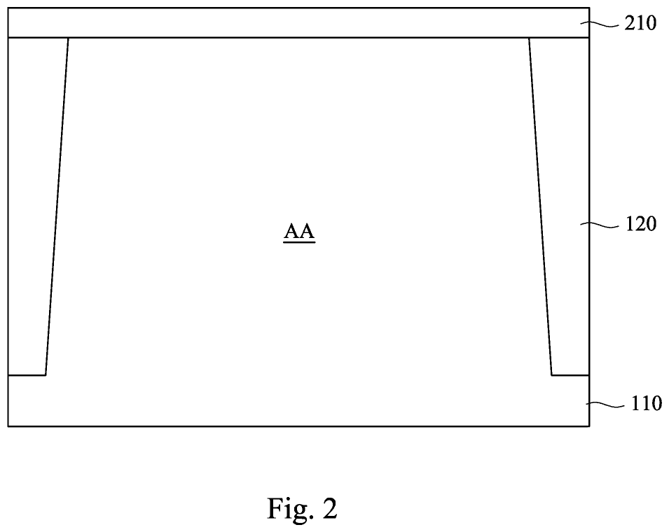

As shown in FIG. 2, a hard mask layer 210 is formed on the substrate 110. In some embodiments, the hard mask layer 210 is a single-layer structure or a multi-layer structure. In some embodiments, the hard mask layer 210 is an insulating oxide layer, such as a silicon oxide layer. In some embodiments, the hard mask layer 210 includes a pad oxide layer on the substrate 110 and a nitride layer on the pad oxide layer. The thickness of the nitride layer can be greater than the thickness of the pad oxide layer.

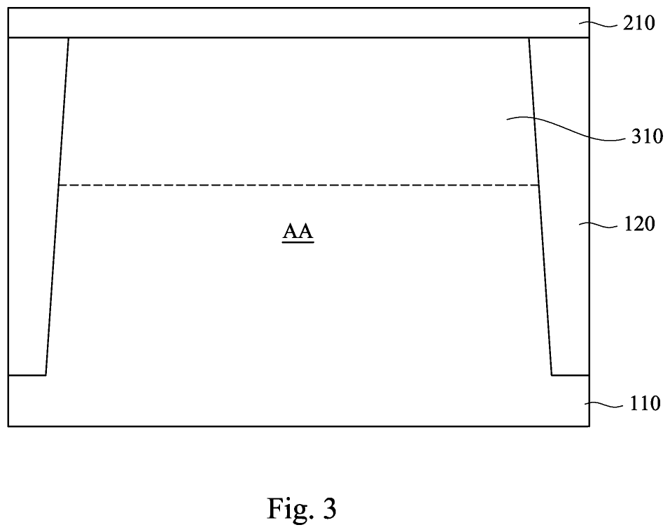

Attention is now invited to FIG. 3. A doped region 310 is formed in the active area AA of the substrate 110. In some embodiments, the active area AA is doped with an N-type dopant, such as phosphorus (P), arsenic (As), or antimony (Sb). In some other embodiments, the active area AA is doped with a P-type dopant, such as boron (B) or indium (In). In some embodiments, the active area AA has a doping concentration higher than that of the substrate 110.

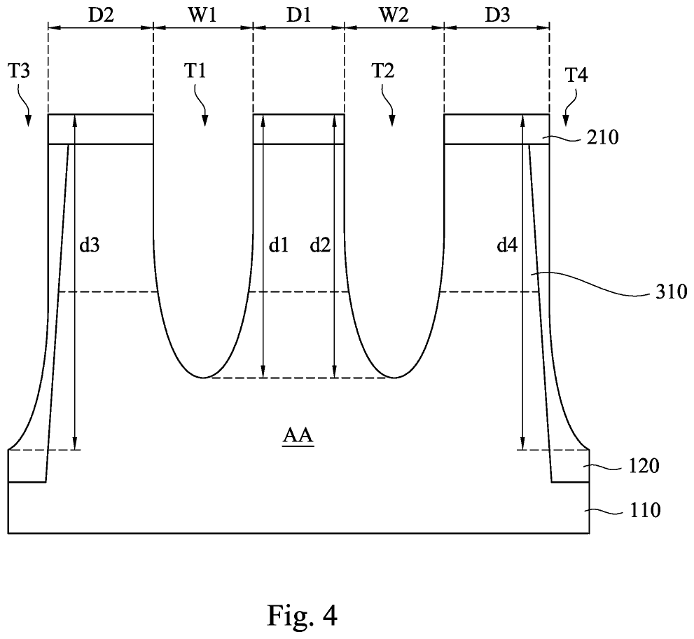

Please refer to FIG. 4. Trenches are formed in the substrate 110. The trenches include a first trench T1, a second trench T2, a third trench T3, and a fourth trench T4. The amount of trenches is not limited to 4 and can be arbitrarily adjusted according to the design requirements. The first trench T1 and the second trench T2 penetrate through the doped region 310. The third trench T3 and the fourth trench T4 penetrate into the isolation structure 120. In some other embodiments, after the trenches are formed in the substrate 110, the doped region 310 is formed in the substrate 110 with the trenches.

In some embodiments, the formation of the trenches includes the following operations. The hard mask layer 210 is formed on the substrate 110. Then a photoresist layer (not shown) is formed on the hard mask layer 210. The photoresist layer is patterned to have openings that expose portions of the hard mask layer 210. An etching process is further performed through the openings of the patterned photoresist layer to remove portions of the hard mask layer 210 and the active area AA that are not protected by the patterned photoresist layer such that the trenches are formed in the active area AA of the substrate 110. The patterned photoresist layer can be removed after trenches are formed. In some embodiments, as shown in FIG. 4, the hard mask layer 210 still remains on the substrate 110 after the trenches are formed.

The first trench T1, the second trench T2, the third trench T3, and the fourth trench T4 may be formed by performing an etching process respectively. The etching process may include a selective wet etching process or a selective dry etching process. In some embodiments, a wet etching solution includes tetramethylammonium hydroxide (TMAH), an HF/HNO₃/CH₃COOH solution, or another suitable solution. In some other embodiments, a wet etching solution includes NH₄OH, KOH, HF, TMAH, other suitable wet etching solutions, or combinations thereof. In some other embodiments, a dry etching process includes a biased plasma etching process that uses a chlorine-based chemical compound. Other dry etchant gasses include CF₄, NF₃, SF₆, or combinations thereof.

In some embodiments, the trenches respectively have a width of 12 nm to 30 nm, such as 12, 14, 16, 18, 20, 22, 24, 26, 28, or 30 nm. For example, the first trench T1 has a first width W1 of 12 nm to 30 nm. For example, the second trench T2 has a second width W2 of 12 nm to 30 nm. In some embodiments, the first trench T1 has a first top edge, the second trench T2 has a second top edge adjacent to the first top edge, and a distance D1 between the first top edge and the second top edge is 12 nm to 30 nm, such as 12, 14, 16, 18, 20, 22, 24, 26, 28, or 30 nm. In some embodiments, the first trench T1 has a first top edge, the third trench T3 has a third top edge adjacent to the first top edge, and a distance D2 between the first top edge and the third top edge is 12 nm to 30 nm, such as 12, 14, 16, 18, 20, 22, 24, 26, 28, or 30 nm. Similarly, in some embodiments, the second trench T2 has a second top edge, the fourth trench T4 has a fourth top edge adjacent to the second top edge, and a distance D3 between the second top edge and the fourth top edge is 12 nm to 30 nm, such as 12, 14, 16, 18, 20, 22, 24, 26, 28, or 30 nm.

In some embodiments, as shown in FIG. 4, a third depth d3 of the third trench T3 and/or a fourth depth d4 of the fourth trench T4 is/are greater than a first depth d1 of the first trench T1 and/or a second depth d2 of the second trench T2, but it is not limited thereto. In some other embodiments, the third depth d3 of the third trench T3 and/or the fourth depth d4 of the fourth trench T4 is/are similar to the first depth d1 of the first trench T1 and/or the second depth d2 of the second trench T2.

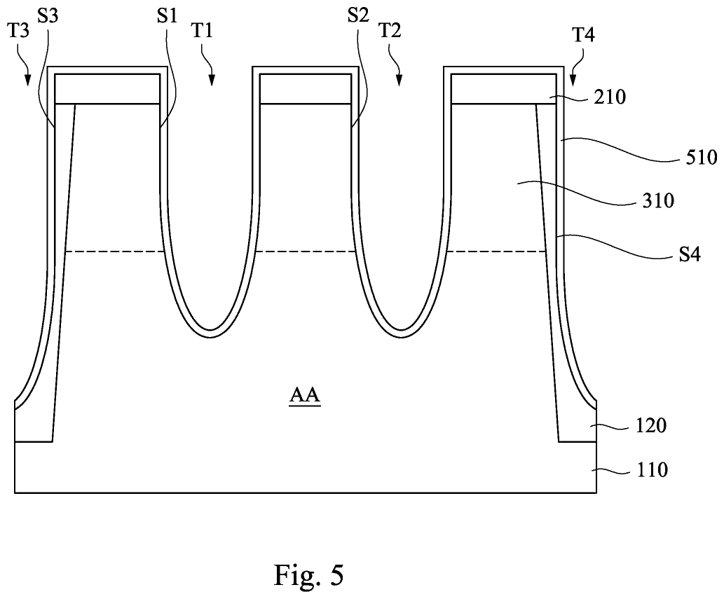

Reference is made to FIG. 5. A dielectric layer 510 is formed to cover a first inner surface S1 of the first trench T1, a second inner surface S2 of the second trench T2, a third inner surface S3 of the third trench T3, and a fourth inner surface S4 of the fourth trench T4. In some embodiments, the dielectric layer 510 conformally covers the first inner surface S1, the second inner surface S2, the third inner surface S3, and the fourth inner surface S4. In some embodiments, the dielectric layer 510 includes one or more layers of a dielectric material, such as silicon oxide, titanium nitride, silicon nitride, or a high-k dielectric material, other suitable dielectric material, and/or combinations thereof. Examples of the high-k dielectric materials include hafnium oxide (HfO₂), hafnium silicate (HfSiO₄), HfSiON, HfTaO, HfTiO, HfZrO, lanthanum oxide (La₂O₃), lanthanum aluminum oxide (LaAlO₃), zirconium oxide (ZrO₂), zirconium silicate (ZrSiO₄), aluminum oxide (Al₂O₃), titanium oxide, hafnium dioxide-alumina (HfO₂—Al₂O₃) alloy, other suitable high-k dielectric materials, and/or combinations thereof. In some embodiments, the dielectric layer 510 is formed by atomic layer deposition (ALD) or atomic layer chemical vapor deposition (ALCVD).

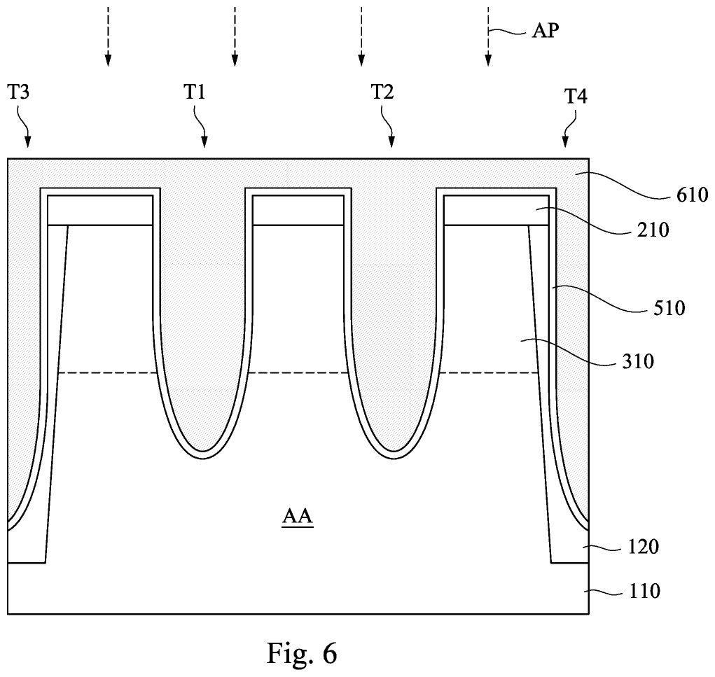

As shown in FIG. 6, a bottom conductive layer 610 is deposited on the dielectric layer 510 and in the first trench T1, the second trench T2, the third trench T3, and the fourth trench T4. In some embodiments, the bottom conductive layer 610 is deposited at a first temperature of 350° C. to 450° C., such as 350, 360, 370, 380, 390, 400, 410, 420, 430, 440, or 450° C. When a deposition temperature falls within the above temperature range, word-line wiggling or word-line collapse can be prevented. If a deposition temperature is lower than 350° C., the gas used for deposition may not be fully reacted. If a deposition temperature is higher than 450° C., word-line wiggling or word-line collapse may occur. In some embodiments, depositing the bottom conductive layer 610 is performed by chemical vapor deposition (CVD) or physical vapor deposition (PVD). In some embodiments, the bottom conductive layer 610 includes titanium nitride. In some embodiments, the bottom conductive layer 610 is a titanium nitride layer. It is noted that even if the portions between the trenches have small widths (such as 12 nm to 30 nm) and/or the trenches have small widths (such as 12 nm to 30 nm), word-line wiggling or word-line collapse can be prevented due to low deposition temperature. The low deposition temperature improves structural stability.

Please still refer to FIG. 6, an annealing process AP is performed on the bottom conductive layer 610 at a second temperature greater than or equal to 470° C. The annealing process AP can lower the resistivity of the bottom conductive layer 610, thereby improving its electrical performance. In some embodiments, the second temperature is 470° C. to 650° C., such as 470, 480, 490, 500, 510, 520, 530, 540, 550, 560, 570, 580, 590, 600, 610, 620, 630, 640, or 650° C. If an annealing temperature is lower than 470° C., the resistivity of the bottom conductive layer 610 may not be effectively reduced. If an annealing temperature is too high, the performance of the overall structure may be affected by excessive heat. In some embodiments, during performing the annealing process AP, an annealing time is between 5 minutes to 100 minutes, such as 5, 10, 15, 20, 25, 30, 35, 40, 45, 50, 55, 60, 65, 70, 75, 80, 85, 90, 95, or 100 minutes. In some embodiments, the annealing process AP is performed by rapid thermal annealing under a temperature, for example, exceeding 1,000° C. for not more than a few seconds. In some embodiments, the annealing process AP is performed under an inert gas atmosphere or a nitrogen gas atmosphere to prevent oxidation of the bottom conductive layer 610.

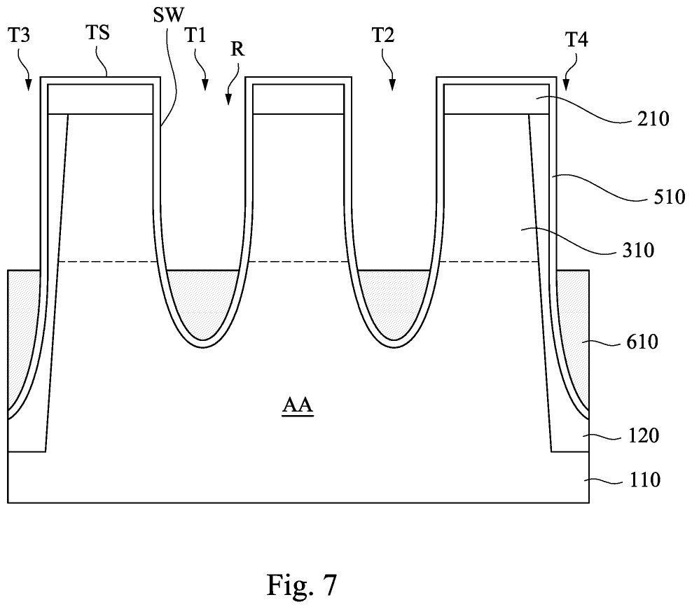

Attention is now invited to FIG. 7. Portions of the bottom conductive layer 610 are removed to form recesses R on the bottom conductive layer 610 and in the first trench T1, the second trench T2, the third trench T3, and the fourth trench T4, respectively. In some embodiments, the portions of the bottom conductive layer 610 are removed to expose a sidewall SW and a top surface TS of the dielectric layer 510.

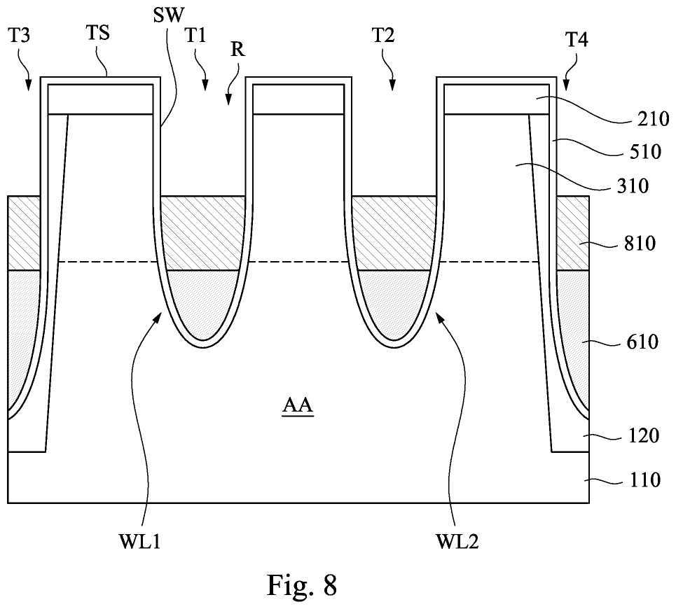

Please refer to FIG. 8. A top conductive layer 810 is formed in the recesses R and on the bottom conductive layer 610. In some embodiments, the top conductive layer 810 includes polysilicon. In some embodiments, the top conductive layer 810 is a polysilicon layer. As shown in FIG. 8, the top conductive layer 810 is in direct contact with the bottom conductive layer 610. In some embodiments, the top conductive layer 810 is formed by the following operations. A conductive layer is formed on the bottom conductive layer 610, in the first trench T1, the second trench T2, the third trench T3, and the fourth trench T4, and on the dielectric layer 510. In some embodiments, the conductive layer includes polysilicon. In some embodiments, the conductive layer is a polysilicon layer. Portion of the conductive layer are removed to expose the sidewall SW and the top surface TS of the dielectric layer 510. Therefore, the remaining portions of the conductive layer are the top conductive layer 810.

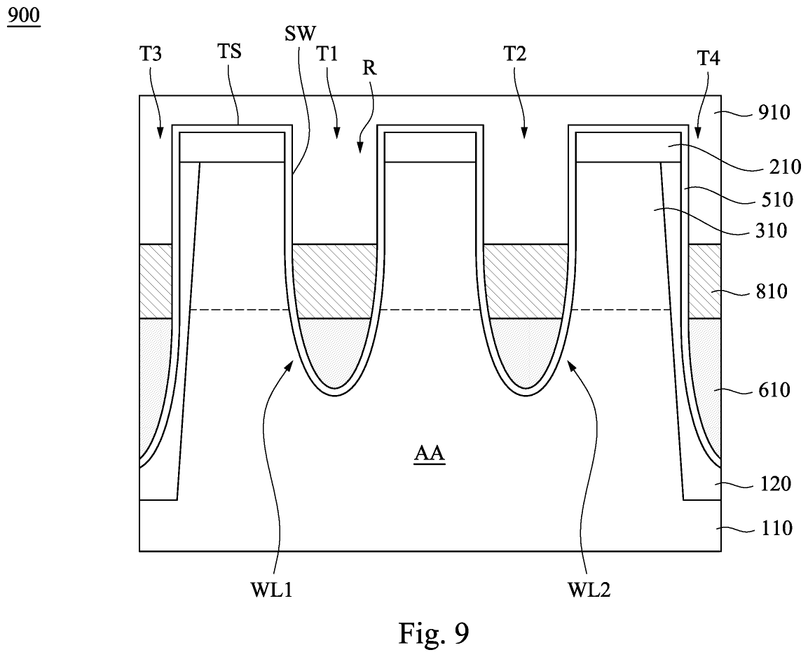

Reference is made to FIG. 9. An insulating capping layer 910 is formed to fill the first trench T1, the second trench T2, the third trench T3, and the fourth trench T4. Therefore, a semiconductor structure 900 is formed. In some embodiments, as shown in FIG. 9, the insulating capping layer 910 covers the top surface TS of the dielectric layer 510. In some other embodiments, a portion of the insulating capping layer 910 is removed to expose the top surface TS of the dielectric layer 510 by, for example, a chemical mechanical polishing (CMP) and/or an etch-back method. In some embodiments, the insulating capping layer 910 comprises an insulating nitride, such as silicon nitride.

The semiconductor structure 900 includes a first word-line structure WL1 and a second word-line structure WL2 that respectively include a portion of the bottom conductive layer 610 and a portion of the top conductive layer 810. Furthermore, as shown in FIG. 9, the doped region 310 includes first source/drain regions and a second source/drain region. In some examples, the second source/drain region between the first word-line structure WL1 and the second word-line structure WL2 may be a source region of the transistors, and the first source/drain regions disposed on opposite sides of each of the first word-line structure WL1 and the second word-line structure WL2 may be drain regions of the transistors. In some embodiments, the semiconductor structure 900 further includes capacitors (not shown) electrically connected to the first source/drain regions, and a bit line contact (not shown) electrically connected to the second source/drain region. Further, the word-line structures in the third trench T3 and the fourth trench T4 may serve as passing word-lines (PWL).

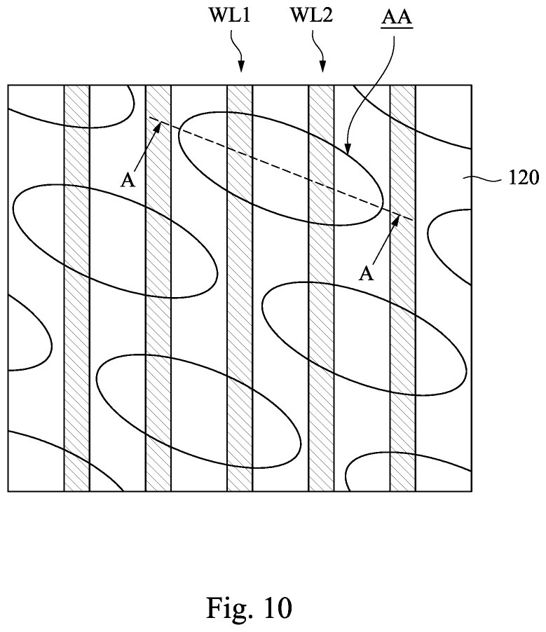

Please refer to FIG. 10. FIG. 10 is a top view of a semiconductor structure in accordance with some embodiments of the present disclosure. In some embodiments, FIG. 8 is a cross-sectional view of the semiconductor structure of FIG. 10 along a section line A-A. In order to clearly show the relative position between the components, some components are omitted in FIG. 10. In some embodiments, the semiconductor structure shown in FIG. 10 is an array transistor, such as a BCAT. As shown in FIG. 8 and FIG. 10, the active areas AA are surrounded and isolated from each other by the isolation structure 120. A portion of the active area AA is disposed between the first word-line structure WL1 and the second word-line structure WL2. Moreover, the first word-line structure WL1 and the second word-line structure WL2 are respectively embedded in the active areas AA and the isolation structure 120.

The following describes the features of the present disclosure more specifically with reference to experiments. Although the following experiments are described, the materials, their amounts and ratios, processing details, processing procedures, etc., may be appropriately varied without exceeding the scope of the present disclosure. Accordingly, this disclosure should not be interpreted restrictively by the experiments described below.

### Experiment 1: Measurement of Resistivity of Titanium Nitride Layers

The methods of forming the titanium nitride layers of Examples 1-4 and Examples 6-8 respectively include depositing a titanium nitride layer in a trench and then performing an annealing process on the titanium nitride layer. The methods of forming the titanium nitride layers of Example 5 and Comparative Example 1 respectively include depositing a titanium nitride layer in a trench. Please refer to Table 1 below for the experimental conditions of Examples 1-8 and Comparative Example 1.

TABLE 1

| | Deposition | Annealing | |
|---|---|---|---|
| | Temperature | Temperature | Annealing |
| | (° C.) | (° C.) | Time (min) |
| Example 1 | 380 | 475 | 20 |
| Example 2 | 380 | 475 | 60 |
| Example 3 | 380 | 525 | 20 |
| Example 4 | 380 | 525 | 60 |
| Example 5 | 420 | N/A | N/A |
| Example 6 | 420 | 525 | 20 |
| Example 7 | 420 | 525 | 60 |
| Example 8 | 420 | 525 | 90 |
| Comparative Example 1 | 475 | N/A | N/A |

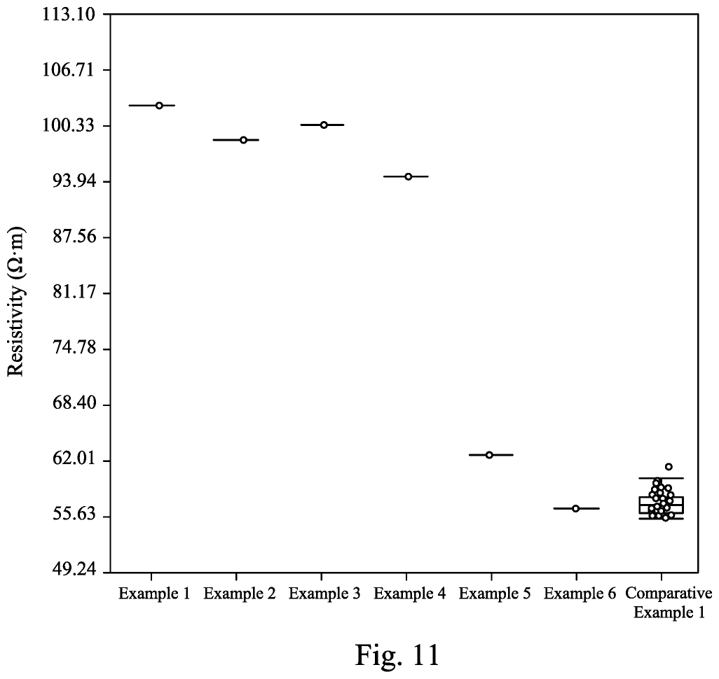

FIG. 11 shows the resistivity of titanium nitride layers in Examples 1-6 and Comparative Example 1 of the present disclosure. It can be seen from Examples 1-4 that the resistivity of the titanium nitride layers can be reduced by increasing the annealing temperature and/or increasing the annealing time. It can be seen from Examples 1-6 that the resistivity of the titanium nitride layers can be reduced by increasing the deposition temperature. It can be seen from Example 6 and Comparative Example 1 that while the deposition temperature of Example 6 was lower than that of Comparative Example 1, the titanium nitride layer of Example 6 can have a resistivity similar to the resistivity of the titanium nitride layer of Comparative Example 1 due to the annealing process.

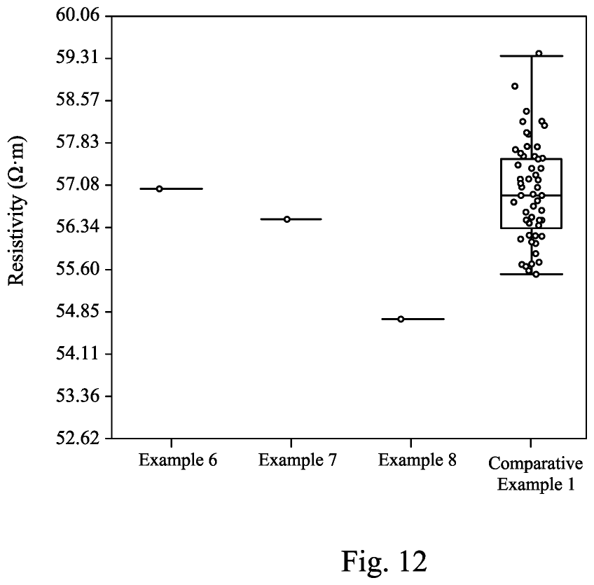

FIG. 12 shows the resistivity of titanium nitride layers of Examples 6-8 and Comparative Example 1 in the present disclosure. It can be seen from Examples 6-8 that the resistivity of the titanium nitride layers can be reduced by increasing the annealing time. It can be seen from Example 8 and Comparative Example 1 that while the deposition temperature of Example 8 was lower than that of Comparative Example 1, the titanium nitride layer of Example 8 can have a resistivity lower than the resistivity of the titanium nitride layer of Comparative Example 1 due to the sufficient annealing time.

### Experiment 2: Measurement of Space Imbalance of Titanium Nitride Layers

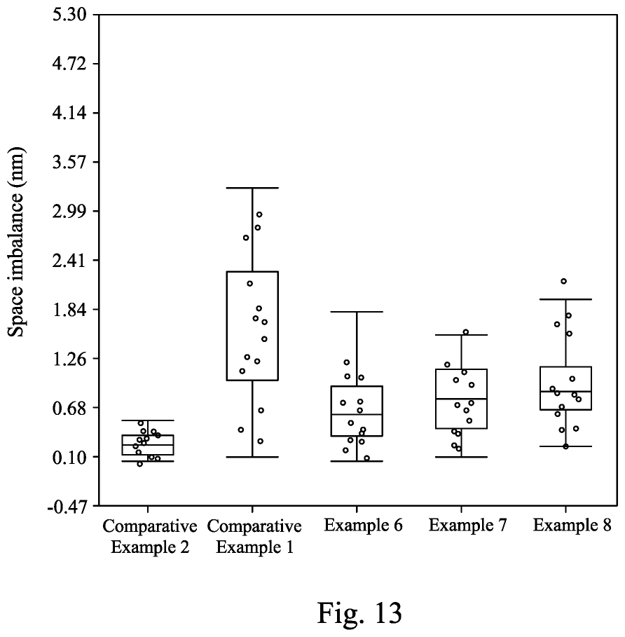

FIG. 13 shows the space imbalance of the titanium nitride layers of Examples 6-8 and Comparative Examples 1-2 in the present disclosure. In Comparative Example 2, the space imbalance of a structure with a trench before depositing a titanium nitride layer in the trench was observed by a scanning electron microscope (SEM). In Comparative Example 1 and Examples 6-8, the space imbalance of the structures respectively with a trench filled with a titanium nitride layer were observed by a SEM. It can be seen from Comparative Example 1 and Examples 6-8 that the titanium nitride layers of Examples 6-8 have a lower space imbalance, which is similar to the space imbalance of Comparative Example 2. This experimental result shows that depositing the titanium nitride layers at low temperatures and performing an annealing process on the titanium nitride layers can effectively improve word-line wiggling.

In conclusion, the present disclosure provides the methods of forming the semiconductor structures, which include the bottom conductive layer and the top conductive layer that can be used as a word-line structure. The methods include simple processes. The methods include depositing the bottom conductive layer in the trench under a lower deposition temperature and then annealing the bottom conductive layer under the annealing temperature higher than the deposition temperature. The bottom conductive layer can have low resistivity, and problems of word-line wiggling or word-line collapse can be prevented.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the present disclosure. In view of the foregoing, it is intended that the present disclosure cover modifications and variations of this disclosure provided they fall within the scope of the following claims.

What is claimed is:

1. A method of forming a semiconductor structure, comprising:
forming a trench in a substrate;
forming a dielectric layer to cover an inner surface of the trench;
depositing a bottom conductive layer on the dielectric layer and in the trench at a first temperature of 350° C. to 450° C.;
performing an annealing process on the bottom conductive layer at a second temperature greater than or equal to 470° C.;
removing a portion of the bottom conductive layer to form a recess on the bottom conductive layer and in the trench; and
forming a top conductive layer in the recess.

2. The method of claim 1, wherein the bottom conductive layer comprises titanium nitride.

3. The method of claim 1, wherein the top conductive layer comprises polysilicon.

4. The method of claim 1, wherein the second temperature is 470° C. to 650° C.

5. The method of claim 1, wherein the annealing process is performed by rapid thermal annealing.

6. The method of claim 1, wherein during performing the annealing process, an annealing time is between 5 minutes to 100 minutes.

7. The method of claim 1, wherein the annealing process is performed under an inert gas atmosphere or a nitrogen gas atmosphere.

8. The method of claim 1, wherein the trench has a width of 12 nm to 30 nm.

9. The method of claim 1, wherein depositing the bottom conductive layer is performed by chemical vapor deposition or physical vapor deposition.

10. The method of claim 1, further comprising:
before forming the trench in the substrate, forming a doped region in the substrate, wherein after forming the trench in the substrate, the trench penetrates through the doped region.

11. A method of forming a semiconductor structure, comprising:
forming a first trench and a second trench in a substrate;
forming a dielectric layer to cover a first inner surface of the first trench and a second inner surface of the second trench;
depositing a titanium nitride layer on the dielectric layer and in the first trench and the second trench at a first temperature of 350° C. to 450° C.; and
performing an annealing process on the titanium nitride layer at a second temperature greater than or equal to 470° C.

12. The method of claim 11, wherein the first trench has a first top edge, the second trench has a second top edge adjacent to the first top edge, and a distance between the first top edge and the second top edge is 12 nm to 30 nm.

13. The method of claim 11, wherein the second temperature is 470° C. to 650° C.

14. The method of claim 11, wherein during performing the annealing process, an annealing time is between 5 minutes to 100 minutes.

15. The method of claim 11, wherein the annealing process is performed by rapid thermal annealing.

16. The method of claim 11, further comprising:
after performing the annealing process on the titanium nitride layer, removing a portion of the titanium nitride layer to expose a sidewall and a top surface of the dielectric layer;
forming a polysilicon layer on the titanium nitride layer and in the first trench and the second trench; and
removing a portion of the polysilicon layer to expose the sidewall and the top surface of the dielectric layer.

17. The method of claim 16, further comprising:
after removing the portion of the polysilicon layer, forming an insulating capping layer to fill the first trench and the second trench.

18. The method of claim 11, further comprising:
before forming the first trench and the second trench in the substrate, forming a doped region in the substrate, wherein after forming the first trench and the second trench in the substrate, the first trench and the second trench penetrate through the doped region.

19. The method of claim 11, wherein a first depth of the first trench is greater than a second depth of the second trench.

20. The method of claim 19, further comprising:
before forming the first trench and the second trench in the substrate, forming an isolation structure in the substrate, wherein after forming the first trench and the second trench in the substrate, the first trench penetrates into the isolation structure.
